(19) United States
(12) Patent Application Publication
(10) Pub. No.: US 2026/0040792 A1
(43) Pub. Date: Feb. 5, 2026

(54) COVER PANEL, COVER PANEL MODULE, AND ELECTRONIC DEVICE

(71) Applicant: Samsung Display Co., Ltd., Yongin-si (KR)

(72) Inventors: YOUNHWAN JUNG, Yongin-si (KR); SEON-KYONG KIM, Yongin-si (KR)

(21) Appl. No.: 19/211,587

(22) Filed: May 19, 2025

(30) Foreign Application Priority Data
Jul. 30, 2024 (KR) 10-2024-0101032

(51) Int. Cl. H10K 59/80

(52) U.S. Cl. CPC H10K 59/871

(57) ABSTRACT

A cover panel includes a support having an upper surface and a lower surface facing the upper surface and a first adhesive layer on the upper surface of the support. At least a portion of the lower surface of the support is a flat surface substantially parallel to a plane defined by a first direction and a second direction perpendicular to the first direction, and the upper surface of the support is a curved surface convex in a third direction perpendicular to the plane. The first adhesive layer has a main portion and a protruding portion, and the protruding portion protrudes from the main portion in a direction opposite to a direction toward a center of the main portion in a plan view.

### CROSS-REFERENCE TO RELATED APPLICATION

This application claims priority to and the benefit of Korean Patent Application No. 10-2024-0101032, filed on Jul. 30, 2024, which is hereby incorporated by reference for all purposes as if fully set forth herein.

### BACKGROUND

### 1. Field

Embodiments of the present disclosure relate to a cover panel, a cover panel module, and an electronic device.

### 2. Description of the Related Art

A cover panel may be attached below a display panel to support the display panel. Before the cover panel is attached to the display panel, release films may be attached to both the upper and lower surfaces of the cover panel to prevent the cover panel from being contaminated or damaged. If lifting occurs between the cover panel and the release film, foreign substances may adhere to the adhesive layer of the cover panel, and the cover panel may become contaminated or damaged.

### SUMMARY

Embodiments of the present disclosure provide a cover panel that prevents or reduces contamination or damage during a manufacturing process of an electronic device.

Embodiments of the present disclosure also provide a cover panel module that prevents or reduces contamination or damage during a manufacturing process of an electronic device.

Embodiments of the present disclosure also provide an electronic device exhibiting improved reliability.

Additional aspects and features of the present disclosure will be set forth in the description that follows and, in part, will be apparent from the description or may be learned by practice of the described embodiments.

A cover panel, according to an embodiment of the present disclosure, includes a support having an upper surface and a lower surface facing the upper surface and a first adhesive layer on the upper surface of the support and having a main portion and a protruding portion. At least a portion of the lower surface of the support is a flat surface substantially parallel to a plane defined by a first direction and a second direction perpendicular to the first direction, and the upper surface of the support is a curved surface convex in a third direction perpendicular to the plane. The protruding portion protrudes from the main portion in a direction opposite to a direction toward a center of the main portion in a plan view.

In an embodiment, the support may cover a lower surface of the main portion of the first adhesive layer and may expose a lower surface of the protruding portion of the first adhesive layer.

In an embodiment, in the plan view, a profile of an outer side surface of the first adhesive layer may be different from a profile of an outer side surface of the support.

In an embodiment, the outer side surface of the first adhesive layer may be formed by an outer side surface of the main portion and an outer side surface of the protruding portion. In the plan view, a profile of the outer side surface of the main portion may be the same as the profile of the outer side surface of the support, and a profile of the outer side surface of the protruding portion may be different from the profile of the outer side surface of the support.

In an embodiment, a planar shape of the main portion of the first adhesive layer may be the same as a planar shape of the support.

In an embodiment, the support may have a circular planar shape. In the plan view, a distance between the center of the support and an outer side surface of the protruding portion of the first adhesive layer may be greater than a distance between the center of the support and an outer side surface of the main portion of the first adhesive layer.

In an embodiment, in the plan view, the distance between the center of the support and the outer side surface of the main portion of the first adhesive layer may be the same as a distance between the center of the support and an outer side surface of the support.

In an embodiment, in the plan view, the distance between the center of the support and the outer side surface of the main portion of the first adhesive layer may be less than a distance between the center of the support and an outer side surface of the support.

In an embodiment, the first adhesive layer may include a plurality of adhesive layers.

In an embodiment, the support may define a first hole, and the first adhesive layer may define a second hole connected to the first hole.

In an embodiment, the cover panel may further include a second adhesive layer on the lower surface of the support and having an area smaller than an area of the support.

A cover panel module, according to an embodiment of the present disclosure, includes a cover panel including a support, a first adhesive layer, and a first release film on an upper surface of the first adhesive layer. The support has an upper surface and a lower surface facing the upper surface. At least a portion of the lower surface of the support is a flat surface substantially parallel to a plane defined by a first direction and a second direction perpendicular to the first direction, and the upper surface of the support is a curved surface convex in a third direction perpendicular to the plane. The first adhesive layer is on the upper surface of the support and includes a main portion and a protruding portion. The protruding portion protrudes from the main portion in a direction opposite to a direction toward a center of the main portion in a plan view.

In an embodiment, the first release film may entirely cover an upper surface of the main portion and an upper surface of the protruding portion.

In an embodiment, the first release film may define a hole having a shape extending along an edge of the main portion of the first adhesive layer in the plan view. In the plan view, the hole may not overlap (e.g., may be offset from) the main portion and the protruding portion.

In an embodiment, the cover panel may further include a second adhesive layer on the lower surface of the support and having an area smaller than an area of the support. The cover panel module may further include a second release film on the lower surface of the support and a lower surface of the second adhesive layer.

An electronic device, according to an embodiment of the present disclosure, includes a cover panel including a support and a first adhesive layer, a cover window on the cover panel, and a display panel between the cover panel and the cover window and including a plurality of pixels. The support has an upper surface and a lower surface facing the upper surface. At least a portion of the lower surface of the support is a flat surface substantially parallel to a plane defined by a first direction and a second direction perpendicular to the first direction, and the upper surface of the support is a curved surface convex in a third direction perpendicular to the plane. The first adhesive layer is on the upper surface of the support and has a main portion and a protruding portion. The protruding portion protrudes from the main portion in a direction opposite to a direction toward a center of the main portion in a plan view.

In an embodiment, the display panel may entirely cover an upper surface of the main portion and an upper surface of the protruding portion.

In an embodiment, an outer side surface of the protruding portion of the first adhesive layer may be between an outer side surface of the support and an outer side surface of the display panel.

In an embodiment, the cover window may have a lower surface facing the display panel and an upper surface opposite to the lower surface. The lower surface of the cover window may be a curved surface concave in the third direction. The upper surface of the cover window may be a curved surface convex in the third direction.

In an embodiment, a curvature radius of the upper surface of the support may be the same as a curvature radius of the lower surface of the cover window.

According to embodiments, during the manufacturing process of the electronic device, lifting between the adhesive layer of the cover panel and the release film may be prevented or reduced. Accordingly, contamination or damage to the cover panel may be reduced or prevented, and reliability of the electronic device may be improved.

It is to be understood that both the foregoing general description and the following detailed description are exemplary and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the of the present disclosure, and together with the description, explain aspects and features of the of the present disclosure.

FIG. 1 is a perspective view illustrating an electronic device according to an embodiment.

FIG. 2 is a cross-sectional view illustrating an electronic device according to an embodiment.

FIG. 3 is a cross-sectional view illustrating a display panel according to an embodiment.

FIG. 4 is an exploded perspective view illustrating a cover panel according to an embodiment.

FIG. 5 is a top view illustrating a cover panel according to an embodiment.

FIG. 6 is a bottom view illustrating a cover panel according to an embodiment.

FIG. 7 is a cross-sectional view taken along the line I-I′ in FIG. 5.

FIG. 8 is a cross-sectional view taken along the line II-II′ in FIG. 5.

FIGS. 9 and 10 are cross-sectional views illustrating a cover panel and a display panel according to an embodiment.

FIG. 11 is an exploded perspective view illustrating a cover panel module according to an embodiment.

FIG. 12 is a top view illustrating a cover panel module according to an embodiment.

FIG. 13 is a bottom view illustrating a cover panel module according to an embodiment.

FIG. 14 is a cross-sectional view taken along the line III-III′ in FIG. 12.

FIG. 15 is a cross-sectional view taken along the line IV-IV′ in FIG. 12.

FIG. 16 is a top view illustrating a cover panel according to an embodiment.

FIG. 17 is a cross-sectional view taken along the line V-V′ in FIG. 16.

FIG. 18 is a top view illustrating a cover panel according to an embodiment.

FIG. 19 is a bottom view illustrating a cover panel according to an embodiment.

FIG. 20 is a block diagram illustrating an electronic device according to an embodiment.

### DETAILED DESCRIPTION

Various example embodiments will be described more fully hereinafter with reference to the accompanying drawings, in which some embodiments of the present disclosure are shown. The present disclosure may, however, be embodied in many different forms and should not be construed as limited to the embodiments set forth herein. Rather, these embodiments are provided so that this disclosure will be thorough and complete and will fully convey the scope of the present disclosure to those skilled in the art.

In the disclosure, various modifications can be made, various forms can be used, and embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted or only briefly repeated.

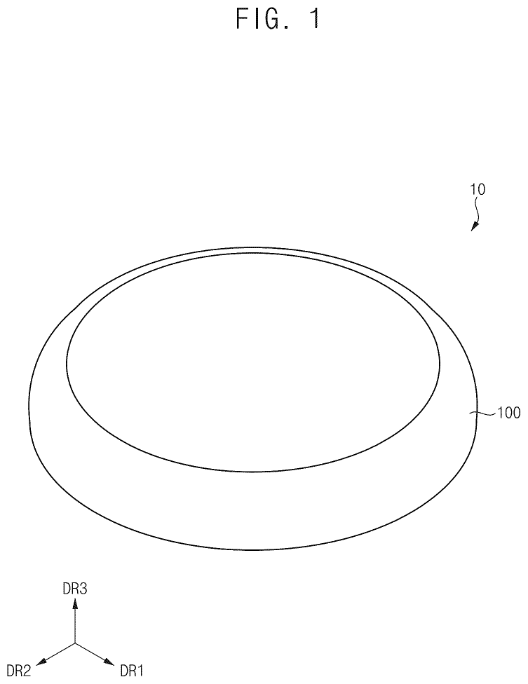

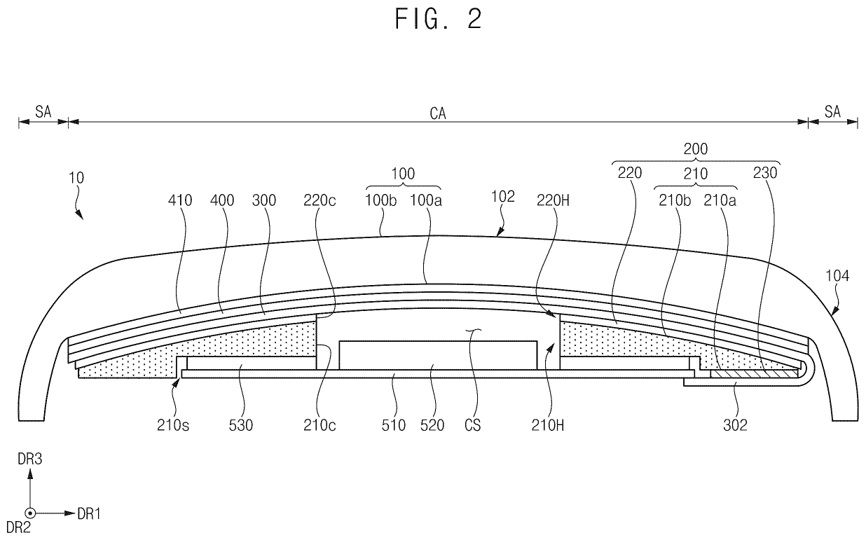

FIG. 1 is a perspective view illustrating an electronic device according to an embodiment. FIG. 2 is a cross-sectional view illustrating an electronic device according to an embodiment.

In this specification, a plane may be defined by a first direction DR1 and a second direction DR2 crossing (e.g., intersecting) the first direction DR1. For example, the first direction DR1 and the second direction DR2 may be perpendicular to each other. An electronic device and various components or layers may have a thickness in a third direction DR3 substantially parallel to a normal direction of the plane. For example, the third direction DR3 may be perpendicular to each of the first direction DR1 and the second direction DR2.

Referring to FIGS. 1 and 2, an electronic device 10 may be a device that is activated according to (or in response to) an electrical signal. For example, the electronic device 10 may be a small electronic device, such as a smart watch, a wearable device, or the like. As another example, the electronic device 10 may be various types of electronic devices, such as a smart phone, a game console, a camera, a laptop, a tablet PC, a television, a computer monitor, a vehicle monitor, an external billboard, or the like. The electronic device 10 may display an image in the third direction DR3. Hereinafter, the third direction DR3, which is the direction in which the electronic device 10 displays an image, may be referred to as an upward direction, and a direction opposite to the third direction DR3 may be referred to as a downward direction.

In an embodiment, the electronic device 10 may have a central area CA and a side area SA. The side area SA may be located around (e.g., may extend around a periphery of) the central area CA. The side area SA may surround the central area CA in a plan view. For example, the entire central area CA of the electronic device 10 may display the image. The side area SA of the electronic device 10 may not display the image, or only a portion of the side area SA may display the image.

In the embodiment illustrated in FIGS. 1 and 2, the central area CA has a circular shape and the side area SA has a circular ring shape in a plan view, but embodiments are not limited thereto. In other embodiments, the central area CA may have various shapes, such as a polygon, a polygon with rounded corners, an oval, or the like.

In an embodiment, the electronic device 10 may include a cover window 100, a cover panel 200, a display panel 300, a polarizing layer 400, a circuit board 510, and an electronic component 520.

The cover window 100 may define the exterior of the electronic device 10. The cover window 100 may protect the display panel 300, the electronic component 520, and/or the like from external impact. The cover window 100 may have light-transmitting properties. The display panel 300 may display the image in the third direction DR3 through the cover window 100. For example, the cover window 100 may include a transparent and hard material, such as glass, plastic, or the like.

The cover window 100 may have a first surface 100a and a second surface 100b facing the first surface 100a. The second surface 100b may be positioned in the third direction DR3 from the first surface 100a. The first surface 100a may be a surface facing the display panel 300, and the second surface 100b may be a surface facing the outside (e.g., facing away from the display panel 300). Hereinafter, the first surface 100a of the cover window 100 may be referred to as a lower surface of the cover window 100, and the second surface 100b of the cover window 100 may be referred to as an upper surface of the cover window 100.

The cover window 100 may have a central portion 102 corresponding to the central area CA and a side portion 104 corresponding to the side area SA. In the embodiment illustrated in FIG. 2, the lower surface 100a of the central portion 102 of the cover window 100 may be a curved surface generally curved with a first curvature radius. The lower surface 100a of the central portion 102 of the cover window 100 may be a curved surface concave in the third direction DR3.

In the embodiment illustrated in FIG. 2, the upper surface 100b of the central portion 102 of the cover window 100 may be a curved surface generally curved with a second curvature radius. The upper surface 100b of the central portion 102 of the cover window 100 may be a curved surface convex in the third direction DR3. For example, in the embodiment illustrated in FIG. 2, the second curvature radius may be greater than the first curvature radius. In another embodiment, the upper surface 100b of the central portion 102 of the cover window 100 may be a flat surface substantially parallel to the plane defined by the first direction DR1 and the second direction DR2.

The side portion 104 of the cover window 100 may extend in the downward direction (e.g., the direction opposite to the third direction DR3) from the central portion 102. In the embodiment illustrated in FIG. 2, the side portion 104 of the cover window 100 may extend to protrude in the downward direction more than (or beyond) other components (e.g., the cover panel 200, the display panel 300, the circuit board 510, the electronic component 520, or the like) of the electronic device 10. For example, the side portion 104 of the cover window 100 may extend in the downward direction from the central portion 102 to surround (e.g., to cover or extend over peripheral edges of) other components of the electronic device 10.

The cover panel 200 may be arranged below the cover window 100. The cover panel 200 may be arranged below the display panel 300. The cover panel 200 may be attached to a lower surface of the display panel 300. The cover panel 200 may protect the display panel 300 from an external environment (e.g., impact, electromagnetic waves, noise, or the like) and may support the display panel 300.

In an embodiment, the cover panel 200 may be arranged below the central portion 102 of the cover window 100. The side portion 104 of the cover window 100 may surround (e.g., may extend around a periphery of) the cover panel 200.

In an embodiment, the cover panel 200 may include a support 210, a first adhesive layer 220, and a second adhesive layer 230.

The support 210 may support the display panel 300. The support 210 may prevent or reduce deformation of the display panel 300 due to external force or the like. The support 210 may act as a support to maintain the display panel 300 in a curved state. The support 210 may have relatively high rigidity. For example, the support 210 may be formed by injection molding a plastic, such as polycarbonate, polyimide, or the like, but this is an example and embodiments are not limited thereto.

The support 210 may have a first surface 210a and a second surface 210b facing the first surface 210a. The second surface 210b of the support 210 may be a surface facing the display panel 300. Hereinafter, the first surface 210a of the support 210 may be referred to as a lower surface of the support 210, and the second surface 210b of the support 210 may be referred to as an upper surface of the support 210.

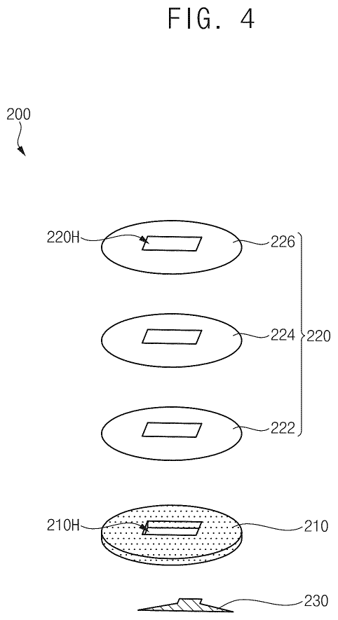

In an embodiment, the support 210 may have a dome structure in which the lower surface 210a is generally flat and the upper surface 210b is convex in the upward direction (see, e.g., FIGS. 2 and 4). At least a portion of the lower surface 210a of the support 210 may be a flat surface substantially parallel to the plane defined by the first direction DR1 and the second direction DR2.

The upper surface 210b of the support 210 may be a curved surface generally curved with a third curvature radius. The upper surface 210b of the support 210 may be a curved surface convex in the third direction DR3. In an embodiment, the upper surface 210b of the support 210 may be curved to correspond to the lower surface 100a of the central portion 102 of the cover window 100. For example, the third curvature radius may be substantially equal to the first curvature radius.

In an embodiment, the support 210 may have a first hole (e.g., a first opening) 210H in the inside (see, e.g., FIGS. 2 and 4) (e.g., at a center or central portion of the support 210). The first hole 210H may penetrate (e.g., may extend through) the support 210 in the third direction DR3. The first hole 210H may be defined by an inner side surface 210c of the support 210. For example, the first hole 210H may have a rectangular planar shape, but this is an example and embodiments are not limited thereto.

In an embodiment, a lower portion of the support 210 may include a step 210s concavely stepped in the third direction DR3. For example, as illustrated in FIG. 2, the lower surface 210a of the support 210 may be concavely stepped from a periphery portion to a central portion.

The first adhesive layer 220 may be arranged on the support 210. The first adhesive layer 220 may be attached to the upper surface 210b of the support 210. For example, the first adhesive layer 220 may be entirely attached to the upper surface 210b of the support 210. The first adhesive layer 220 may attach the support 210 to the lower surface of the display panel 300. For example, a lower surface of the first adhesive layer 220 may be attached to the upper surface 210b of the support 210, and an upper surface of the first adhesive layer 220 may be attached to the lower surface of the display panel 300. The first adhesive layer 220 may be curved along a shape of the upper surface 210b of the support 210. In an embodiment, the first adhesive layer 220 may include a plurality of adhesive layers. This will be described in more detail later with reference to FIG. 4.

In an embodiment, the first adhesive layer 220 may have a second hole (e.g., a second opening) 220H in the inside (see, e.g., FIGS. 2 and 4) (e.g., at a center or central portion of the first adhesive layer 220). The second hole 220H may penetrate (e.g., may extend through) the first adhesive layer 220 in the third direction DR3. The second hole 220H may be defined by an inner side surface 220c of the first adhesive layer 220. The second hole 220H may have a planar shape corresponding to planar shape of the first hole 210H. For example, the second hole 220H may have a rectangular planar shape, but this is an example and embodiments are not limited thereto. The first hole 210H and the second hole 220H may be connected to (e.g., may be aligned with) each other and may define an accommodation space CS together.

The second adhesive layer 230 may be arranged below the support 210. The second adhesive layer 230 may be attached to the lower surface 210a of the support 210. For example, the second adhesive layer 230 may be attached to a portion of the lower surface 210a of the support 210. The second adhesive layer 230 may have an area smaller than an area of the support 210. The second adhesive layer 230 may attach one end portion 302 of the display panel 300, described below, to the support 210.

In an embodiment, the cover panel 200 may further include additional functional layers, such as a heat dissipation layer, a shielding layer, or the like. The cover panel 200 will be described in more detail later with reference to FIGS. 4 to 10.

The display panel 300 may be arranged on the cover panel 200. The display panel 300 may be arranged between the cover window 100 and the cover panel 200. The display panel 300 may include a plurality of pixels for generating the image. The image may be generated by combining the light emitted by each of the pixels. For example, the pixels may be arranged in a matrix form in the first direction DR1 and the second direction DR2, but embodiments are not limited thereto.

In an embodiment, the display panel 300 may be arranged below the central portion 102 of the cover window 100. The side portion 104 of the cover window 100 may surround (e.g., may extend around a periphery of) the display panel 300.

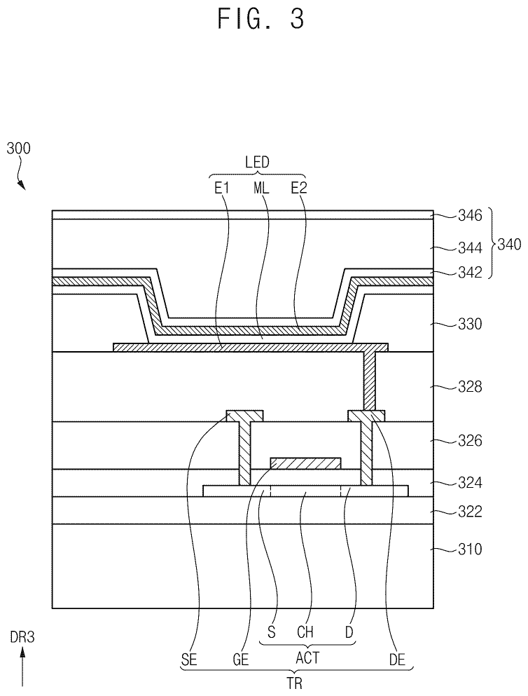

FIG. 3 is a cross-sectional view illustrating a display panel according to an embodiment.

Hereinafter, a cross-sectional structure of the display panel 300 will be described in detail with reference to FIG. 3.

Referring to FIG. 3, in an embodiment, the display panel 300 may include a substrate 310, a buffer layer 322, the pixels, first to third insulating layers 324, 326, and 328, a pixel defining layer 330, and an encapsulation layer 340. Each of the pixels may include a pixel circuit including at least one transistor TR and a light emitting element LED. The pixel circuit may further include at least one capacitor.

The substrate 310 may form a base of the display panel 300. The substrate 310 may be an insulating substrate including (or formed of) a transparent or a non-transparent material. The substrate 310 may include plastic and may be flexible. The display panel 300 may be a flexible display panel. The substrate 310 may have a single layer structure or a multi-layer structure including a plurality of layers including different materials.

The buffer layer 322 may be arranged on the substrate 310. The buffer layer 322 may prevent or reduce impurities, such as oxygen or moisture, from penetrating into an upper portion of the substrate 310 through the substrate 310. The buffer layer 322 may include an inorganic material. In an embodiment, for example, the buffer layer 322 may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These materials may be used alone or in combination with each other. The buffer layer 322 may have a single layer structure or a multi-layer structure including a plurality of insulating layers.

The transistor TR may be arranged on the buffer layer 322. The transistor TR may include an active layer ACT, a gate electrode GE, a first contact electrode SE, and a second contact electrode DE.

The active layer ACT may be arranged on the buffer layer 322. The active layer ACT may include an oxide semiconductor, a silicon semiconductor, an organic semiconductor, or the like. In an embodiment, for example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may have a first contact area S, a second contact area D, and a channel area CH between the first contact area S and the second contact area D. Each of the first contact area S and the second contact area D may have higher conductivity than a conductivity of the channel area CH.

The first insulating layer 324 may be arranged on the active layer ACT. The first insulating layer 324 may cover the active layer ACT on the buffer layer 322. The first insulating layer 324 may include an inorganic insulating material.

The gate electrode GE may be arranged on the first insulating layer 324. The gate electrode GE may overlap the channel area CH of the active layer ACT. The gate electrode GE may include a conductive material, such as a metal, an alloy, a conductive metal nitride, a conductive metal oxide, a transparent conductive material, or the like. For example, the gate electrode GE may include gold (Au), silver (Ag), aluminum (AI), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single layer structure or a multi-layer structure including a plurality of conductive layers.

The second insulating layer 326 may be arranged on the gate electrode GE. The second insulating layer 326 may cover the gate electrode GE on the first insulating layer 324. The second insulating layer 326 may include an inorganic insulating material.

The first contact electrode SE and the second contact electrode DE may be arranged on the second insulating layer 326. The first contact electrode SE and the second contact electrode DE may be connected to the first contact area S and the second contact area D of the active layer ACT, respectively. Each of the first contact electrode SE and the second contact electrode DE may include a conductive material.

The third insulating layer 328 may be arranged on the first contact electrode SE and the second contact electrode DE. The third insulating layer 328 may include an organic insulating material. In an embodiment, for example, the third insulating layer 328 may include a photoresist, a polyacryl-based resin, a polyimide-based resin, a polyamide-based resin, a siloxane-based resin, an acryl-based resin, an epoxy-based resin, or the like. These materials may be used alone or in combination with each other.

The light emitting element LED may be arranged on the third insulating layer 328. The light emitting element LED may include a first electrode E1, an intermediate layer ML, and a second electrode E2.

The first electrode E1 may be arranged on the third insulating layer 328. The first electrode E1 may include a conductive material. The first electrode E1 may be connected to the second contact electrode DE through a contact hole (e.g., a contact opening) formed in the third insulating layer 328. Accordingly, the first electrode E1 may be electrically connected to the transistor TR. For example, the first electrode E1 may be an anode of the light emitting element LED.

The pixel defining layer PDL may be arranged on the first electrode E1. The pixel defining layer PDL may cover a peripheral portion of the first electrode E1 and may define a pixel opening exposing a central portion of the first electrode E1. The pixel opening may define an emission area. The pixel defining layer PDL may include an organic insulating material. In an embodiment, the pixel defining layer PDL may further include an inorganic material or an organic material including (or containing) a light blocking material having a black color.

The intermediate layer ML may be arranged on the first electrode E1 and the pixel defining layer 330. A portion of the intermediate layer ML may be arranged in the pixel opening in the pixel defining layer 330. In an embodiment, the intermediate layer ML may include a first functional layer including an organic material, an emission layer arranged on the first functional layer and including an emission material, and a second functional layer arranged on the emission layer and including an organic material. For example, the first functional layer may include a hole injection layer, a hole transport layer, or the like, and the second functional layer may include an electron transport layer, an electron injection layer, or the like.

In an embodiment, the emission layer may include at least one of an organic light emitting material or a quantum dot, but embodiments are not limited thereto.

In an embodiment, the organic light emitting material may include a low molecular weight organic compound or a high molecular weight organic compound. Examples of the low molecular weight organic compound may include copper phthalocyanine, N,N′-diphenylbenzidine, tris-(8-hydroxyquinoline)aluminum, or the like. Examples of the high molecular weight organic compound may include poly(3,4-ethylenedioxythiophene), polyaniline, poly-phenylenevinylene, polyfluorene, or the like. These materials can be used alone or in a combination thereof.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may act as a protection layer preventing the core from being chemically denatured to maintain its semiconductor characteristics and may act as a charging layer for imparting electrophoretic characteristics to the quantum dot.

The second electrode E2 may be arranged on the intermediate layer ML. The second electrode E2 may include a conductive material. For example, the second electrode E2 may be a cathode of the light emitting element LED.

The encapsulation layer 340 may be arranged on the second electrode E2. The encapsulation layer 340 may include at least one inorganic encapsulation layer and at least one organic encapsulation layer. In an embodiment, the encapsulation layer 340 may include a first inorganic encapsulation layer 342 arranged on the second electrode E2, an organic encapsulation layer 344 arranged on the first inorganic encapsulation layer 342, and a second inorganic encapsulation layer 346 arranged on the organic encapsulation layer 344. In addition, various functional layers, such as a touch sensing layer, a color filter layer, a light collecting layer, or the like may be additionally arranged on the encapsulation layer 340.

Referring again to FIGS. 1 and 2, in an embodiment, the display panel 300 (or the substrate 310 shown in FIG. 3) may be bent such that one end portion 302 of the display panel 300 may be located below the support 210. The one end portion 302 of the display panel 300 may be attached to the support 210 by the second adhesive layer 230. The circuit board 510 may be connected to the one end portion 302 of the display panel 300.

In another embodiment, a flexible circuit film may be connected to one end portion of the display panel 300. The flexible circuit film may have a first end portion and a second end portion. The first end portion of the flexible circuit film may be connected to the one end portion of the display panel 300. The flexible circuit film may be bent such that the second end portion is located below the support 210. The circuit board 510 may be connected to the second end portion of the flexible circuit film.

The polarizing layer 400 may be arranged on the display panel 300. The polarizing layer 400 may be arranged between the cover window 100 and the display panel 300. The polarizing layer 400 may be attached to the lower surface 100a of the cover window 100 by an adhesive layer 410. The polarizing layer 400 may reduce reflection of external light by the electronic device 10. In an embodiment, the polarizing layer 400 may be omitted.

The circuit board 510 may be connected to the one end portion 302 of the display panel 300. The circuit board 510 may be arranged below the cover panel 200. For example, the circuit board 510 may be attached to the lower surface 210a of the support 210 by an adhesive layer 530. In an embodiment, the adhesive layer 530 may have a circular ring shape defining a third hole (e.g., a third opening) in the inside (e.g., at a center or central area of the adhesive layer 530), but embodiments are not limited thereto. The third hole in the adhesive layer 530 may define the accommodation space CS together with the first hole 210H and the second hole 220H.

The electronic component 520 may be arranged on the circuit board 510. The electronic component 520 may be located in the accommodation space CS. The electronic component 520 may include various components for driving the electronic device 10, such as a processor, a battery, a memory, or the like.

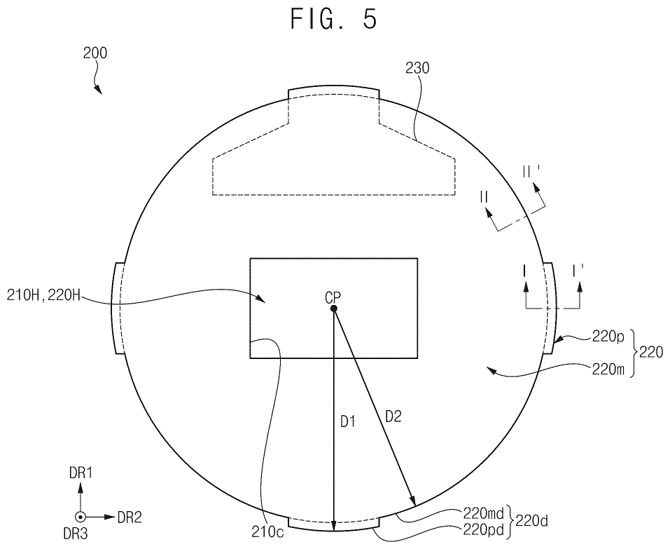

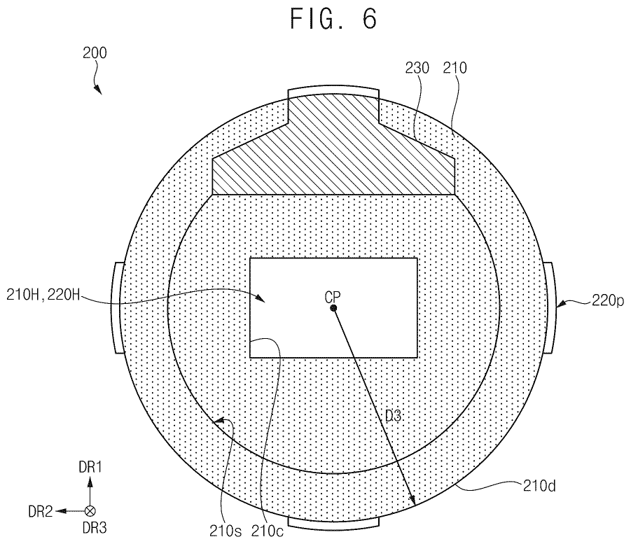

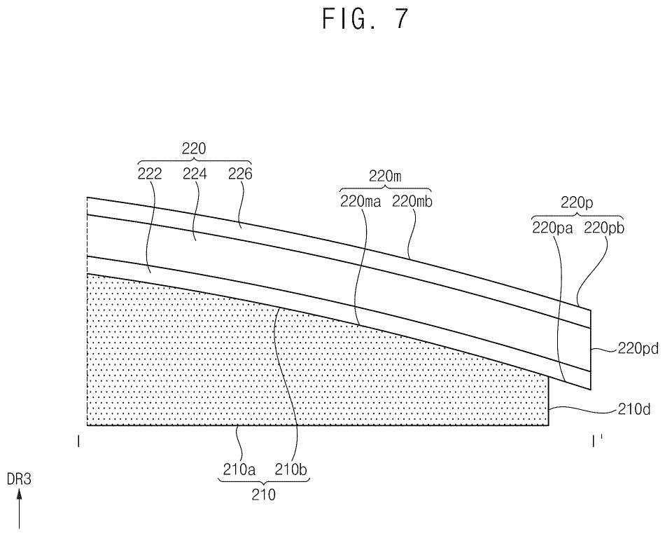

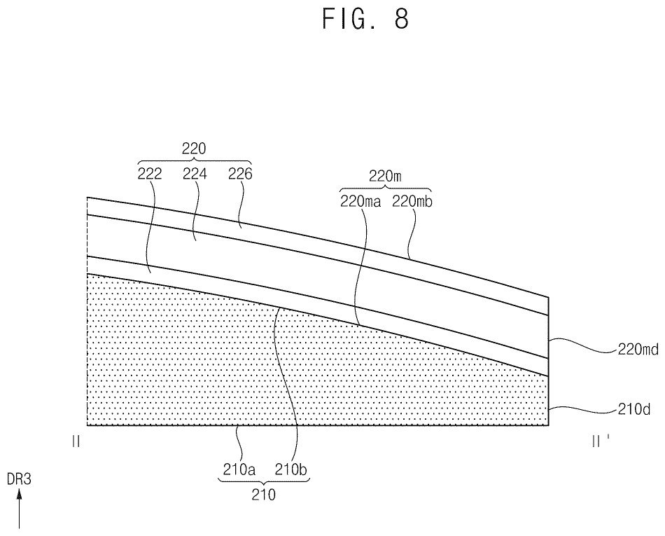

FIG. 4 is an exploded perspective view illustrating a cover panel according to an embodiment. FIG. 5 is a top view illustrating a cover panel according to an embodiment. FIG. 6 is a bottom view illustrating a cover panel according to an embodiment. FIG. 7 is a cross-sectional view taken along the line I-I′ in FIG. 5. FIG. 8 is a cross-sectional view taken along the line II-II′ in FIG. 5.

Referring to FIG. 2 and FIGS. 4 to 8, the cover panel 200 may include the support 210, the first adhesive layer 220, and the second adhesive layer 230. The support 210 may have a dome structure in which the lower surface 210a is generally flat and the upper surface 210b is convex in the upward direction. The inner side surface 210c of the support 210 may define the first hole 210H.

The first adhesive layer 220 may be arranged on the upper surface 210b of the support 210. The first adhesive layer 220 may be attached to the upper surface 210b of the support 210 in a curved state corresponding to the upper surface 210b of the support 210. The cover panel 200 including the support 210 and the first adhesive layer 220 may have a dome structure in which a lower surface is generally flat and an upper surface is convex in the upward direction. The inner side surface 220c of the first adhesive layer 220 may define the second hole 220H. In an embodiment, the first adhesive layer 220 may have a multi-layer structure including a plurality of adhesive layers.

In an embodiment, the first adhesive layer 220 may include first to third layers 222, 224, and 226. For example, the second layer 224 may include embossed patterns each protruding in the third direction DR3 or in a direction opposite to the third direction DR3. The first layer 222 may attach the second layer 224 to the support 210. The third layer 226 may attach the second layer 224 to the display panel 300. For example, each of the first to third layers 222, 224, and 226 may have adhesiveness on both upper and lower surfaces thereof. Hereinafter, the lower surface of the first adhesive layer 220 may refer to the lower surface of the first layer 222, which is the lowest layer, and the upper surface of the first adhesive layer 220 may refer to the upper surface of the third layer 226, which is the highest (or uppermost) layer.

In an embodiment, the first to third layers 222, 224, and 226 may have substantially the same planar shape as each other. For example, the first adhesive layer 220 may be formed by cutting an adhesive film in which three adhesive layers are stacked. Accordingly, side surfaces of the first to third layers 222, 224, and 226 may be aligned with each other. In addition, FIG. 4 illustrates an embodiment in which the first adhesive layer 220 includes three adhesive layers, but this is an example and embodiments are not limited thereto. For example, the first adhesive layer 220 may include one, two, or four or more adhesive layers.

As illustrated in FIGS. 5 and 6, the first adhesive layer 220 may have a main portion 220m and at least one protruding portion 220p that protrudes an outward direction (e.g., that protrudes outwardly) from the main portion 220m in a plan view. As described above, the first to third layers 222, 224, and 226 may have substantially the same planar shape. In such an embodiment, each of the first to third layers 222, 224, and 226 included in the first adhesive layer 220 may have a main portion and at least one protruding portion.

The main portion 220m of the first adhesive layer 220 may be a portion attached to the upper surface 210b of the support 210. As illustrated in FIGS. 7 and 8, the main portion 220m of the first adhesive layer 220 may have a lower surface 220ma and an upper surface 220mb facing each other. For example, the entire lower surface 220ma of the main portion 220m of the first adhesive layer 220 may be attached to the upper surface 210b of the support 210. For example, the entire main portion 220m of the first adhesive layer 220 may not protrude in outward direction (e.g., a direction opposite to a direction toward a center of the support 210 from the support 210) in a plan view. In other words, the support 210 may entirely cover the lower surface 220ma of the main portion 220m of the first adhesive layer 220.

The main portion 220m of the first adhesive layer 220 may have a planar shape corresponding to the planar shape of the support 210. For example, when the support 210 has a circular planar shape defining the first hole 210H in the inside, the main portion 220m of the first adhesive layer 220 may have a circular planar shape defining the second hole 220H in the inside. As illustrated in FIGS. 5 and 6, in a plan view, a center of the main portion 220m of the first adhesive layer 220 may coincide with (e.g., may be aligned with) the center of the support 210. Hereinafter, the center of the main portion 220m of the first adhesive layer 220 and the center of the support 210 are collectively referred to as a center point CP. That is, the center point CP may refer to the center of the main portion 220m of the first adhesive layer 220 or the center of the support 210. In addition, an inward direction may refer to a direction toward the center point CP, and the outward direction may refer to a direction opposite to a direction toward the center point CP.

In a plan view, the protruding portion 220p of the first adhesive layer 220 may protrude in the outward direction from the main portion 220m. In a plan view, the protruding portion 220p of the first adhesive layer 220 may protrude in the outward direction from the support 210. The protruding portion 220p of the first adhesive layer 220 may be a portion that is not attached to the upper surface 210b of the support 210. As illustrated in FIG. 7, the protruding portion 220p of the first adhesive layer 220 may have a lower surface 220pa and an upper surface 220pb facing each other. The support 210 may not cover the lower surface 220pa of the protruding portion 220p of the first adhesive layer 220 and may expose the lower surface 220pa of the protruding portion 220p of the first adhesive layer 220.

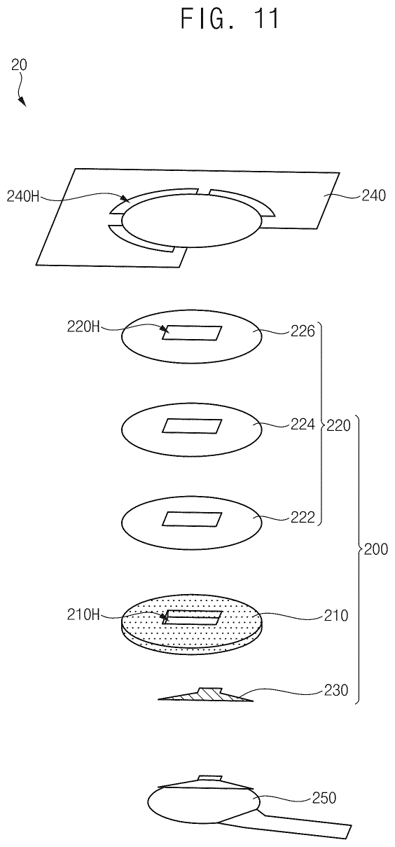

In an embodiment, the protruding portion 220p of the first adhesive layer 220 may include a plurality of protruding portions 220p. For example, FIG. 5 illustrates an embodiment in which the first adhesive layer 220 includes four protruding portions 220p respectively provided on the upper, lower, left, and right sides in a plan view, but this is an example and embodiments are not limited thereto. The protruding portions 220p of the first adhesive layer 220 will be described in more detail later with reference to FIGS. 11 to 15.

An outer side surface 210d of the support 210 may be defined as an outermost side surface of the support 210. For example, as illustrated in FIG. 6, in a plan view, a profile of the outer side surface 210d of the support 210 may be circular.

The outer side surface 220d of the first adhesive layer 220 may be defined as the outermost side surface of the first adhesive layer 220. The main portion 220m and the protruding portion 220p of the first adhesive layer 220 may be integrally provided (or integrally formed). The outer side surface 220d of the first adhesive layer 220 may include an outer side surface 220md of the main portion 220m and an outer side surface 220pd of the protruding portion 220p. For example, in an area at where the protruding portion 220p is not provided, the outer side surface 220md of the main portion 220m may be the outer side surface of the first adhesive layer 220, and in an area at where the protruding portion 220p is provided, the outer side surface 220pd of the protruding portion 220p may be the outer side surface of the first adhesive layer 220.

As illustrated in FIGS. 5 and 7, the outer side surface 220pd of the protruding portion 220p of the first adhesive layer 220 may protrude in (e.g., may protrude beyond) the outward direction (e.g., a right direction in FIG. 7) from the outer side surface 210d of the support 210.

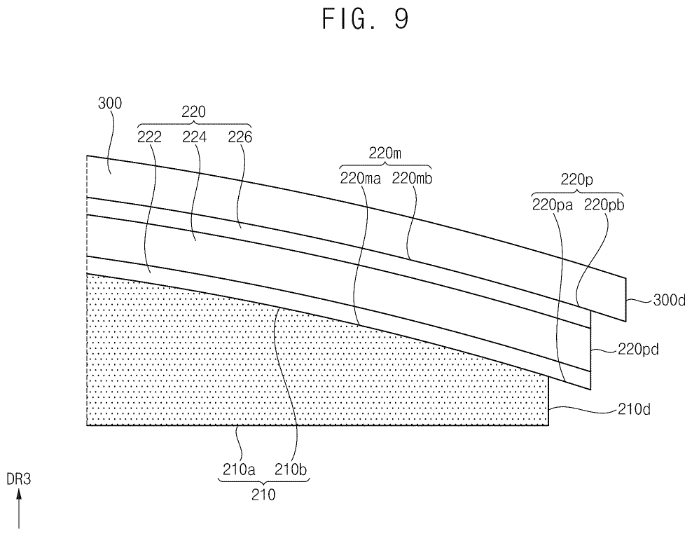

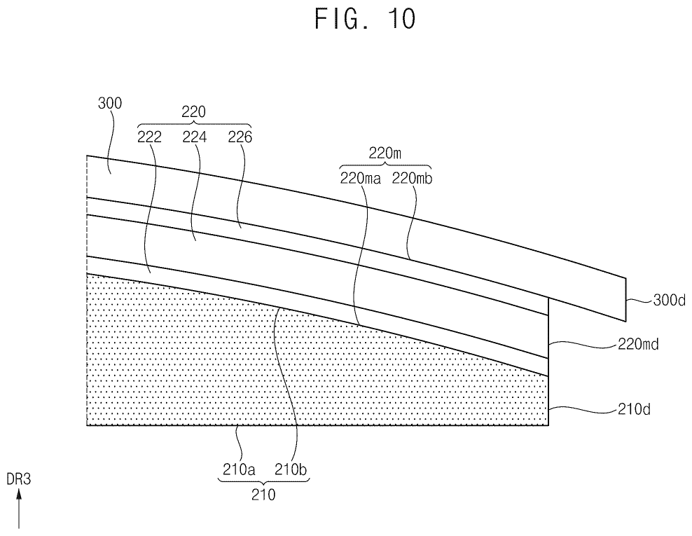

FIGS. 9 and 10 are cross-sectional views illustrating a cover panel and a display panel according to an embodiment. FIG. 9 may correspond to FIG. 7, and FIG. 10 may correspond to FIG. 8. FIGS. 9 and 10 may illustrate a state in which the display panel 300 is attached to the first adhesive layer 220 as shown in FIGS. 7 and 8, respectively.

Referring to FIGS. 9 and 10, an outer side surface 300d of the display panel 300 may protrude in the outward direction (e.g., a right direction in each of FIGS. 9 and 10) from the outer side surface 210d of the support 210.

In an embodiment, as illustrated in FIG. 9, the outer side surface 220pd of the protruding portion 220p of the first adhesive layer 220 may be located between the outer side surface 210d of the support 210 and the outer side surface 300d of the display panel 300. For example, the outer side surface 220pd of the protruding portion 220p of the first adhesive layer 220 may be located in the outward direction (e.g., a right direction in FIG. 9) from the outer side surface 210d of the support 210 and may be located in the inward direction (e.g., a left direction in FIG. 9) from the outer side surface 300d of the display panel 300.

The display panel 300 may entirely cover the upper surface of the first adhesive layer 220. The display panel 300 may cover the entire upper surface 220mb of the main portion 220m of the first adhesive layer 220 and the entire upper surface 220pb of the protruding portion 220p of the first adhesive layer 220. For example, the entire upper surface 220mb of the main portion 220m of the first adhesive layer 220 and the entire upper surface 220pb of the protruding portion 220p of the first adhesive layer 220 may be attached to the lower surface of the display panel 300. The first adhesive layer 220 may be formed such that the protruding portion 220p protrudes in the outward direction (e.g., the right direction in FIG. 9) from the support 210 and does not protrude in (e.g., does not protrude beyond) the outward direction from the display panel 300.

Referring again to FIGS. 5 and 6, in a plan view, a profile of the outer side surface 220d of the first adhesive layer 220 may be different from the profile of the outer side surface 210d of the support 210. As described above, in a plan view, the profile of the outer side surface 210d of the support 210 may be circular. For example, as illustrated in FIG. 5, in a plan view, the profile of the outer side surface 220d of the first adhesive layer 220 may be a deformed circular in which some portions protruded convexly in the outward direction. In a plan view, the profile of the outer side surface 220md of the main portion 220m of the first adhesive layer 220 may be equal to the corresponding profile of the outer side surface 210d of the support 210. In a plan view, the profile of the outer side surface 220pd of the protruding portion 220p of the first adhesive layer 220 may be different from the corresponding profile of the outer side surface 210d of the support 210.

In an embodiment, the main portion 220m of the first adhesive layer 220 may have a planar shape substantially the same as (or substantially corresponding to) the planar shape of the support 210. For example, as illustrated in FIGS. 5 and 8, the outer side surface 220md of the main portion 220m of the first adhesive layer 220 may be aligned with the outer side surface 210d of the support 210.

In an embodiment, in a plan view, a first distance D1 between the center point CP and the outer side surface 220pd of the protruding portion 220p of the first adhesive layer 220 may be greater than a second distance D2 between the center point CP and the outer side surface 220md of the main portion 220m of the first adhesive layer 220. In a plan view, a third distance D3 between the center point CP and the outer side surface 210d of the support 210 may be less than the first distance D1. For example, the second distance D2 may be substantially equal to the third distance D3.

The second adhesive layer 230 may be attached to the lower surface 210a of the support 210. The second adhesive layer 230 may have adhesiveness on both the upper and lower surfaces thereof. The upper surface of the second adhesive layer 230 may be attached to the lower surface 210a of the support 210, and the lower surface of the second adhesive layer 230 may be attached to one surface of the one end portion 302 of the display panel 300 (or one surface of the flexible circuit film). The second adhesive layer 230 may have a planar shape corresponding to a planar shape of the one end portion 302 of the display panel 300 (or a planar shape of the flexible circuit film).

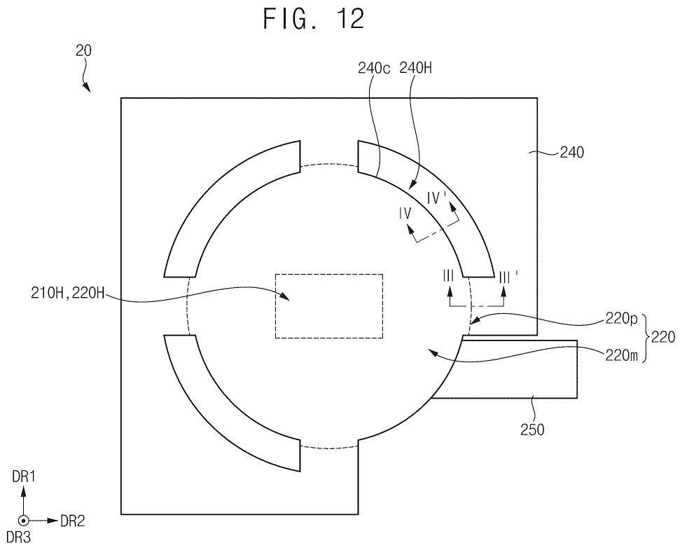

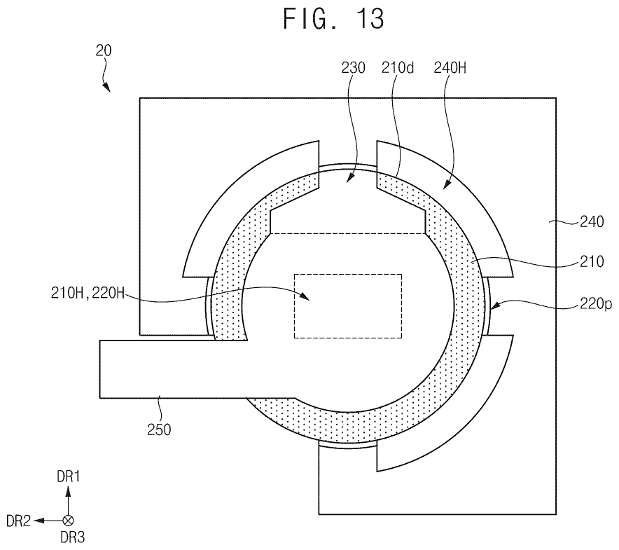

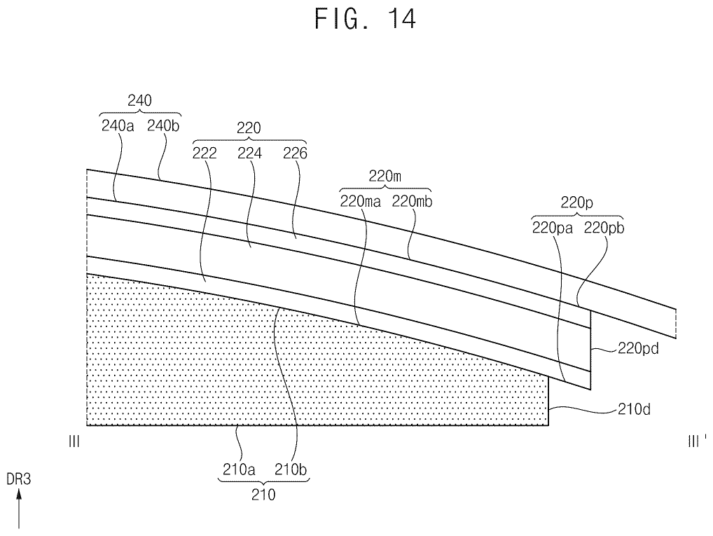

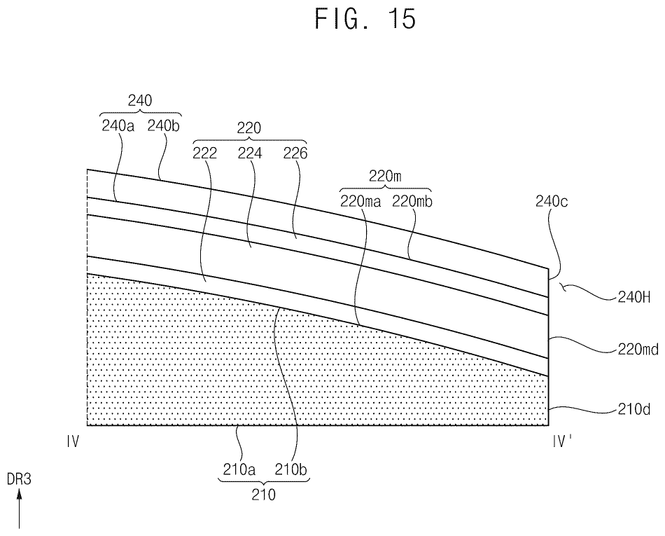

FIG. 11 is an exploded perspective view illustrating a cover panel module according to an embodiment. FIG. 12 is a top view illustrating a cover panel module according to an embodiment. FIG. 13 is a bottom view illustrating a cover panel module according to an embodiment. FIG. 14 is a cross-sectional view taken along the line III-III′ in FIG. 12. FIG. 15 is a cross-sectional view taken along the line IV-IV′ in FIG. 12.

Referring to FIGS. 11 and 15, before the cover panel 200, described above with reference to FIGS. 4 to 8, is attached to the display panel 300 shown in FIG. 2, a first release film 240 and a second release film 250 are attached to the cover panel 200 to form a cover panel module 20.

The first release film 240 may be arranged on the cover panel 200. The first release film 240 may be arranged on the upper surface of the first adhesive layer 220. The first release film 240 may be attached to the upper surface of the first adhesive layer 220. The first release film 240 may be attached to the first adhesive layer 220 until before the first adhesive layer 220 is attached to the display panel 300, thereby protecting the first adhesive layer 220 and preventing or reducing foreign substances from adhering to the first adhesive layer 220. The first release film 240 may be removed from the first adhesive layer 220 immediately before the first adhesive layer 220 is attached to the display panel 300.

The first release film 240 may have a lower surface 240a and an upper surface 240b facing each other. The lower surface 240a of the first release film 240 may not have adhesiveness or may have a relatively small adhesiveness. The upper surface 240b of the first release film 240 may not have adhesiveness.

The first release film 240 may entirely cover the upper surface of the first adhesive layer 220. The first release film 240 may entirely cover the upper surface 220mb of the main portion 220m of the first adhesive layer 220 and the upper surface 220pb of the protruding portion 220p of the first adhesive layer 220. That is, the entire upper surface 220mb of the main portion 220m of the first adhesive layer 220 and the entire upper surface 220pb of the protruding portion 220p of the first adhesive layer 220 may be attached to the lower surface 240a of the first release film 240. The first release film 240 may cover the second hole 220H in the first adhesive layer 220.

In the embodiment illustrated in FIG. 12, the first release film 240 may define at least one hole (e.g., one opening) 240H in the inner side. The hole 240H may penetrate (e.g., may extend through) the first release film 240 in the third direction DR3. The hole 240H may be defined by an inner side surface 240c of the first release film 240.

In one embodiment, the hole 240H may have a shape extending along an edge of the main portion 220m of the first adhesive layer 220 in a plan view. In a plan view, the hole 240H may adjoin the main portion 220m of the first adhesive layer 220. For example, as illustrated in FIG. 15, the outer side surface 220md of the main portion 220m of the first adhesive layer 220 may be aligned with the inner side surface 240c of the first release film 240 defining the hole 240H.

In a plan view, the hole 240H in the first release film 240 may not overlap (e.g., may be offset from) the main portion 220m and the protruding portion 220p of the first adhesive layer 220. The first release film 240 may cover the entire upper surface 220mb of the main portion 220m of the first adhesive layer 220 and the entire upper surface 220pb of the protruding portion 220p of the first adhesive layer 220 and may not expose the entire upper surface 220mb of the main portion 220m of the first adhesive layer 220 and the entire upper surface 220pb of the protruding portion 220p of the first adhesive layer 220.

As described above, the cover panel 200 including the support 210 and the first adhesive layer 220 may have a dome structure in which the lower surface is generally flat and the upper surface is convex in the upward direction. Because the upper surface of the first adhesive layer 220 is a curved surface convex in the upward direction, lifting between an edge portion of the first adhesive layer 220 and the first release film 240 may occur. In this case, the cover panel 200 may be contaminated or damaged, such as foreign substances adhering to an upper surface of the edge portion of the first adhesive layer 220.

According to embodiments, because the first release film 240 defines the hole 240H extending along the edge of the main portion 220m of the first adhesive layer 220, lifting between the edge portion of the first adhesive layer 220 and the first release film 240 may be reduced. FIG. 13 illustrates an embodiment in which the first release film 240 defines three holes 240H spaced apart from each other, but this is an example and embodiments are not limited thereto.

In addition, the first adhesive layer 220 may include the protruding portion 220p that protrudes in the outward direction from the main portion 220m. The protruding portion 220p of the first adhesive layer 220 may be attached to the lower surface 240a of the first release film 240 without overlapping the hole 240H in the first release film 240. Because the protruding portion 220p of the first adhesive layer 220 is attached to the lower surface 240a of the first release film 240 while protruding in the outward direction from the support 210, lifting between the edge portion of the first adhesive layer 220 and the first release film 240 may be further reduced. Accordingly, foreign substances may be prevented from adhering to the upper surface of the first adhesive layer 220 during the manufacturing process of the electronic device, and contamination or damage to the cover panel 200 may be reduced or prevented. Therefore, a reliability of the electronic device 10 may be improved.

The second release film 250 may be arranged below the cover panel 200. The second release film 250 may be arranged on the lower surface 210a of the support 210 and the lower surface of the second adhesive layer 230.

In an embodiment, the second release film 250 may have a first portion attached to the lower surface of the second adhesive layer 230, a second portion attached to the lower surface 210a of the support 210, and a third portion not attached to the lower surface 210a of the support 210 and exposed. For example, the second portion of the second release film 250 may be attached to the lower surface 210a of the central portion of the support 210 that is concavely stepped and may cover the first hole 210H in the support 210. The second release film 250 may be attached to the lower surface 210a of the support 210 and the lower surface of the second adhesive layer 230 until before the cover panel 200 is attached to the display panel 300, thereby protecting the support 210 and the second adhesive layer 230 and preventing or reducing foreign substances from adhering to the second adhesive layer 230.

The second release film 250 may have a lower surface and an upper surface facing each other. The lower surface of the second release film 250 may not have adhesiveness. The upper surface of the second release film 250 may have a relatively small adhesiveness.

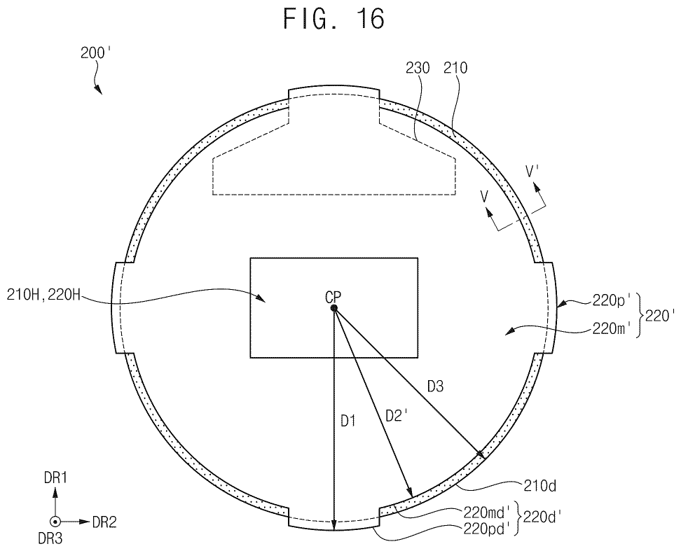

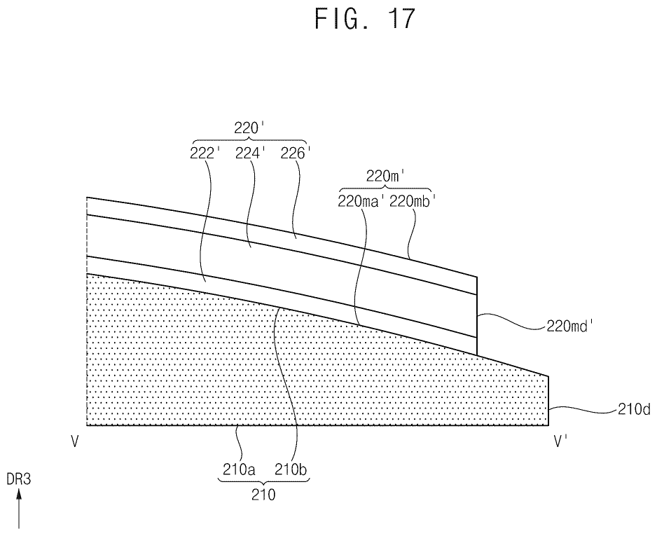

FIG. 16 is a top view illustrating a cover panel according to an embodiment. FIG. 17 is a cross-sectional view taken along the line V-V′ in FIG. 16.

FIG. 16 may correspond to FIG. 5, and FIG. 17 may correspond to FIG. 8. A cover panel 200′ shown in FIGS. 16 and 17 may be substantially the same as the cover panel 200 described above with reference to FIGS. 4 to 8 except for a first adhesive layer 220′. Hereinafter, the cover panel 200′ will be described by focusing primarily on the differences with respect to the cover panel 200 described above with reference to FIGS. 4 to 8, and repeated description of the same or substantially similar components and/or configurations will be omitted or simplified.

Referring to FIGS. 16 and 17, the cover panel 200′ may include the support 210, the first adhesive layer 220′, and the second adhesive layer 230. The support 210 may have a dome structure in which the lower surface 210a is generally flat and the upper surface 210b is convex in the upward direction.

The first adhesive layer 220′ may be attached to the upper surface 210b of the support 210. The cover panel 200′ including the support 210 and the first adhesive layer 220′ may have a dome structure in which the lower surface is generally flat and the upper surface is convex in the upward direction. In an embodiment, the first adhesive layer 220′ may have a multi-layer structure including a plurality of adhesive layers 222′, 224′, and 226′.

A first adhesive layer 220′ may include a main portion 220m′ and at least one protruding portion 220p′ that protrudes in the outward direction from the main portion 220m′ in a plan view.

The main portion 220m′ of the first adhesive layer 220′ may have a lower surface 220ma′ and an upper surface 220mb′ facing each other. For example, the entire lower surface 220ma′ of the main portion 220m′ of the first adhesive layer 220′ may be attached to the upper surface 210b of the support 210. In an embodiment, the main portion 220m′ of the first adhesive layer 220′ may not cover an outer portion of the upper surface 210b of the support 210 and may expose the outer portion of the upper surface 210b of the support 210.

In a plan view, the protruding portion 220p′ of the first adhesive layer 220′ may protrude in the outward direction from the main portion 220m′. In a plan view, an outer portion of the protruding portion 220p′ of the first adhesive layer 220′ may protrude in the outward direction from the support 210.

The outer side surface 210d of the support 210 may be defined as an outermost side surface of the support 210. An outer side surface 220d′ of the first adhesive layer 220′ may be defined as the outermost side surface of the first adhesive layer 220′. The main portion 220m′ and the protruding portion 220p′ of the first adhesive layer 220′ may be integrally provided (or integrally formed). The outer side surface 220d′ of the first adhesive layer 220′ may include an outer side surface 220md′ of the main portion 220m′ and an outer side surface 220pd′ of the protruding portion 220p′. For example, in an area at where the protruding portion 220p′ is not provided, the outer side surface 220md′ of the main portion 220m′ may be the outer side surface of the first adhesive layer 220′, and in an area at where the protruding portion 220p′ is provided, the outer side surface 220pd′ of the protruding portion 220p′ may be the outer side surface of the first adhesive layer 220′.

As illustrated in FIG. 17, the outer side surface 220md′ of the main portion 220m′ of the first adhesive layer 220′ may be located in the inward direction (e.g., a left direction in FIG. 17) from the outer side surface 210d of the support 210. In a plan view, a profile of the outer side surface 220d′ of the first adhesive layer 220′ may be different from the profile of the outer side surface 210d of the support 210.

In an embodiment, in a plan view, a first distance D1 between the center point CP and the outer side surface 220pd′ of the protruding portion 220p′ of the first adhesive layer 220′ may be greater than a second distance D2′ between the center point CP and the outer side surface 220md′ of the main portion 220m′ of the first adhesive layer 220′. In a plan view, a third distance D3 between the center point CP and the outer side surface 210d′ of the support 210′ may be less than the first distance D1. As illustrated in FIG. 16, the second distance D2′ may be less than the third distance D3.

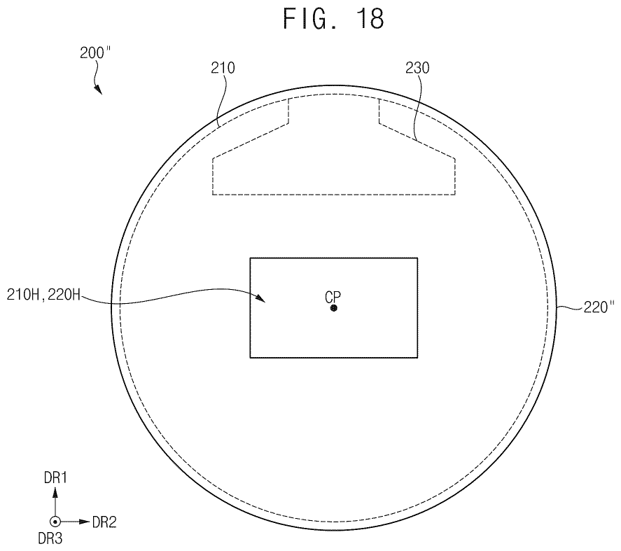

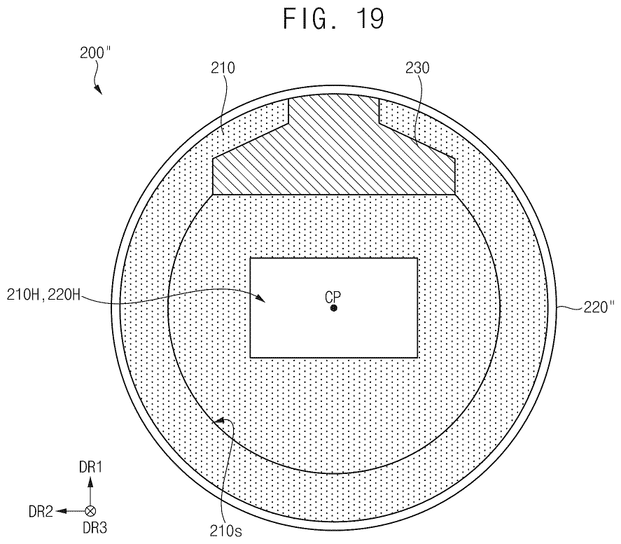

FIG. 18 is a top view illustrating a cover panel according to an embodiment. FIG. 19 is a bottom view illustrating a cover panel according to an embodiment.

FIG. 18 may correspond to FIG. 5, and FIG. 19 may correspond to FIG. 6. A cover panel 200″ shown in FIGS. 18 and 19 may be substantially the same as the cover panel 200 described above with reference to FIGS. 4 to 8 except for a first adhesive layer 220″. Hereinafter, the cover panel 200″ will be described by primarily focusing on the differences with respect to the cover panel 200 described above with reference to FIGS. 4 to 8, and repeated description of the same and substantially similar components and/or configurations will be omitted or simplified.

Referring to FIGS. 18 and 19, the cover panel 200″ may include the support 210, the first adhesive layer 220″, and the second adhesive layer 230. The support 210 may have a dome structure in which the lower surface 210a is generally flat and the upper surface 210b is convex in the upward direction.

The first adhesive layer 220″ may be attached to the upper surface 210b of the support 210. The cover panel 200″ including the support 210 and the first adhesive layer 220″ may have a dome structure in which the lower surface is generally flat and the upper surface is convex in the upward direction. In an embodiment, the first adhesive layer 220″ may have a multi-layer structure including a plurality of adhesive layers.

The first adhesive layer 220″ may have a planar shape corresponding to the planar shape of the support 210. For example, when the support 210 has a circular planar shape defining the first hole 210H in the inside, the first adhesive layer 220″ may have a circular planar shape defining the second hole 220H in the inside.

In an embodiment, in a plan view, a center of the first adhesive layer 220″ may coincide with the center of the support 210. An area of the first adhesive layer 220″ may be greater than an area of the support 210. In a plan view, an edge portion of the first adhesive layer 220″ may protrude in (e.g., may protrude beyond in) the outward direction from the support 210. In a plan view, the edge portion of the first adhesive layer 220″ may have a circular ring shape. The support 210 may not cover a lower surface of the edge portion of the first adhesive layer 220″ and may expose the lower surface of the edge portion of the first adhesive layer 220″.

Referring to FIG. 11 together with FIGS. 18 and 19, the first release film 240 attached to the upper surface of the first adhesive layer 220″ may define at least one hole 240H in the inner side. In an embodiment, the hole 240H may overlap a portion of the edge portion of the first adhesive layer 220″. For example, the portion of the edge portion of the first adhesive layer 220″ may not be attached to the lower surface of the first release film 240 and may be exposed by the hole 240H, and the remaining portion of the edge portion of the first adhesive layer 220″ may be attached to the lower surface of the first release film 240. Because the remaining portion of the edge portion of the first adhesive layer 220″ protrudes in the outward direction from the support 210 and is attached to the lower surface of the first release film 240, lifting between the edge portion of the first adhesive layer 220″ and the second release film 240 may be reduced.

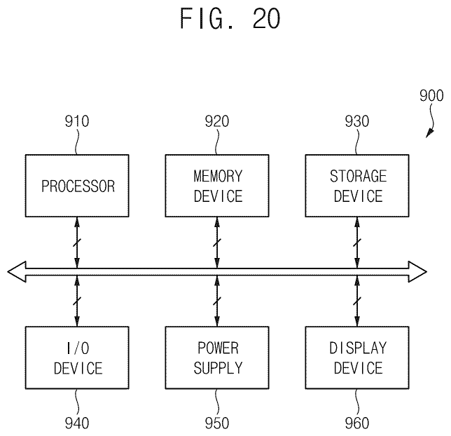

FIG. 20 is a block diagram describing an electronic device according to an embodiment.

Referring to FIG. 20, in an embodiment, an electronic device 900 may include a processor 910, a memory device 920, a storage device 930, an input/output (“I/O”) device 940, a power supply 950, and a display device 960. Here, the electronic device 900 may correspond to the electronic device 10 described above, and the display device 960 may include the display panel 300 described above. The electronic device 900 may further include a plurality of ports for communicating with a video card, a sound card, a memory card, a universal serial bus (“USB”) device, or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device, such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device, such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device, such as a keyboard, a keypad, a mouse device, a touchpad, a touch-screen, or the like, and an output device, such as a printer, a speaker, or the like.

The power supply 950 may provide power for operations of the electronic device 900. The display device 960 may be coupled to other components via the buses or other communication links. In an embodiment, the display device 960 may be included in the I/O device 940.

Although embodiments and implementations have been described herein, other embodiments and modifications will be apparent from this description. Accordingly, the present disclosure is not limited to such embodiments, but rather to the broader scope of the appended claims and their equivalents as would be apparent to a person of ordinary skill in the art.

What is claimed is:

1. A cover panel comprising:
a support having an upper surface and a lower surface facing the upper surface, at least a portion of the lower surface of the support being a flat surface substantially parallel to a plane defined by a first direction and a second direction perpendicular to the first direction, the upper surface of the support being a curved surface convex in a third direction perpendicular to the plane; and
a first adhesive layer on the upper surface of the support and having a main portion and a protruding portion, the protruding portion protruding from the main portion in a direction opposite to a direction toward a center of the main portion in a plan view.

2. The cover panel of claim 1, wherein the support covers a lower surface of the main portion of the first adhesive layer and exposes a lower surface of the protruding portion of the first adhesive layer.

3. The cover panel of claim 1, wherein, in the plan view, a profile of an outer side surface of the first adhesive layer is different from a profile of an outer side surface of the support.

4. The cover panel of claim 3, wherein the outer side surface of the first adhesive layer is formed by an outer side surface of the main portion and an outer side surface of the protruding portion, and
wherein, in the plan view, a profile of the outer side surface of the main portion is the same as the profile of the outer side surface of the support, and a profile of the outer side surface of the protruding portion is different from the profile of the outer side surface of the support.

5. The cover panel of claim 1, wherein a planar shape of the main portion of the first adhesive layer is the same as a planar shape of the support.

6. The cover panel of claim 5, wherein the support has a circular planar shape, and
wherein, in the plan view, a distance between the center of the support and an outer side surface of the protruding portion of the first adhesive layer is greater than a distance between the center of the support and an outer side surface of the main portion of the first adhesive layer.

7. The cover panel of claim 6, wherein, in the plan view, the distance between the center of the support and the outer side surface of the main portion of the first adhesive layer is equal to a distance between the center of the support and an outer side surface of the support.

8. The cover panel of claim 6, wherein, in the plan view, the distance between the center of the support and the outer side surface of the main portion of the first adhesive layer is less than a distance between the center of the support and an outer side surface of the support.

9. The cover panel of claim 1, wherein the first adhesive layer comprises a plurality of adhesive layers.

10. The cover panel of claim 1, wherein the support defines a first hole, and
wherein the first adhesive layer defines a second hole connected to the first hole.

11. The cover panel of claim 1, further comprising a second adhesive layer on the lower surface of the support and having an area smaller than an area of the support.

12. A cover panel module comprising:
a cover panel comprising:
a support having an upper surface and a lower surface facing the upper surface, at least a portion of the lower surface of the support being a flat surface substantially parallel to a plane defined by a first direction and a second direction perpendicular to the first direction, the upper surface of the support being a curved surface convex in a third direction perpendicular to the plane; and
a first adhesive layer on the upper surface of the support and having a main portion and a protruding portion, the protruding portion protruding from the main portion in a direction opposite to a direction toward a center of the main portion in a plan view; and
a first release film on an upper surface of the first adhesive layer.

13. The cover panel module of claim 12, wherein the first release film entirely covers an upper surface of the main portion and an upper surface of the protruding portion.

14. The cover panel module of claim 12, wherein the first release film defines a hole having a shape extending along an edge of the main portion of the first adhesive layer in the plan view, and
wherein, in the plan view, the hole does not overlap the main portion and the protruding portion.

15. The cover panel module of claim 12, further comprising a second release film,
wherein the cover panel further comprises a second adhesive layer on the lower surface of the support and having an area smaller than an area of the support, and
wherein the second release film is on the lower surface of the support and a lower surface of the second adhesive layer.

16. An electronic device comprising:
a cover panel comprising:
a support having an upper surface and a lower surface facing the upper surface, at least a portion of the lower surface of the support being a flat surface substantially parallel to a plane defined by a first direction and a second direction perpendicular to the first direction, the upper surface of the support being a curved surface convex in a third direction perpendicular to the plane; and
a first adhesive layer on the upper surface of the support and having a main portion and a protruding portion, the protruding portion protruding from the main portion in a direction opposite to a direction toward a center of the main portion in a plan view;
a cover window on the cover panel; and
a display panel between the cover panel and the cover window and comprising a plurality of pixels.

17. The electronic device of claim 16, wherein the display panel entirely covers an upper surface of the main portion and an upper surface of the protruding portion.

18. The electronic device of claim 16, wherein an outer side surface of the protruding portion of the first adhesive layer is between an outer side surface of the support and an outer side surface of the display panel.

19. The electronic device of claim 16, wherein the cover window has a lower surface facing the display panel and an upper surface opposite to the lower surface,
wherein the lower surface of the cover window is a curved surface concave in the third direction, and
wherein the upper surface of the cover window is a curved surface convex in the third direction.

20. The electronic device of claim 19, wherein a curvature radius of the upper surface of the support is the same as a curvature radius of the lower surface of the cover window.
